(19) United States
(12) Patent Application Publication
(10) Pub. No.: US 2002/0121018 A1
(43) Pub. Date: Sep. 5, 2002

(54) Component feeding method

(76) Inventors: Kunio Sakurai, Osaka (JP); Wataru Hirai, Osaka (JP); Minoru Yamamoto, Osaka (JP); Seiichi Mogi, Osaka (JP)

Correspondence Address: WENDEROTH, LIND & PONACK, L.L.P., 2033 K STREET N. W., SUITE 800, WASHINGTON, DC, 20006-1021, US

(21) Appl. No.: 10/106,050

(22) Filed: Mar. 27, 2002

Related U.S. Application Data
(63) Continuation of application No. 08/983,445, filed on Jan. 9, 1998.
Application No. 08/983,445 is a 371 of international application No. PCT/JP96/01942, filed on Jul. 12, 1996.

(30) Foreign Application Priority Data
Jul. 12, 1995 (JP) 7-175796

(51) Int. Cl. H05K 3/30; B23P 19/00

(52) U.S. Cl. 29/836; 29/834; 29/740

(57) ABSTRACT

The present invention provides for an electronic component mounting method and apparatus which are capable of achieving high-speed operation by varying a driving amount for an intermittent feed of an electronic component according to the electronic component's type. In order to achieve this purpose, the present invention provides an electronic component mounting method for picking up an electronic component by a pickup nozzle from a component feed unit that intermittently feeds electronic components, and mounting the picked-up electronic component onto a board. A driving amount for the component feed unit for intermittently feeding the electronic components is varied depending on the type of the electronic component.

This application is a Continuation application of application Serial No. 08/983,445 filed Jan. 9, 1998.

BACKGROUND OF THE INVENTION

1. Field of the Invention

The present invention relates to an electronic component mounting method and apparatus by which an electronic component is automatically mounted to a specified position on an electronic circuit board.

2. State of the Prior Art

A conventional electronic component mounting apparatus, as shown in FIGS. 10A and 10B, comprises a component feed unit 50 for sequentially feeding out a plurality of components and a cam lever mechanism 51 for driving the component feed unit 50 to a specified component feed position.

The component feed unit 50, which is loaded with a carrier tape containing multiple components, forwardly feeds the tape by a pitch corresponding to a push amount each time a feed lever 54 is pushed. The component feed unit 50 feeds out the components one by one to a specified feed-out position 55. The components at the specified feed-out position 55 are vacuum-picked up (sucked) by a component pickup head 59 that is used for component mounting.

The cam lever mechanism 51 transfer a motion of a bell crank 53 driven by a cam 52, to a feed driving lever 56 via a rod 57. The resulting swing of the feed driving lever 56 causes a roller 58, provided at its end, to contact the feed lever 54, and thereby push feed lever 54 by a certain amount in order to feed the component.

In this case, using the cam lever mechanism 51 makes it possible to mechanically synchronize a sequence of operations, such as the feeding of a component, and the rotational and up-and-down driving motion of the pickup nozzle. This in turn makes it possible to have a reliable electronic component mounting apparatus.

In the above prior art example, one cam lever mechanism 51 is uniformly used to drive the component feed unit 50. However, the amount to which an electronic component is intermittently fed varies depending on the size/type of the electronic component. One issue is that a smaller amount of intermittent feed causes a loss of the swinging stroke of the roller 58 which makes it impossible to obtain a higher speed. Small-size electronic components allow the mounting apparatus to be operated at higher speeds so that higher-speed mounting can be achieved. Small-size electronic components can have smaller intermittent feed amounts so that higher-speed mounting can be achieved by reducing the driving amount for the feed lever 54. However, the component feed unit 50 is conventionally driven uniformly regardless of the electronic component's type so that highspeed mounting cannot be realized. Particularly, when large-size electronic components and small-size electronic components are intermingled, high-speed mounting can hardly be achieved. In such a case, a plurality of mounting apparatuses would be required to mount electronic components depending on the types of electronic components. This results in lower productivity and poorer cost performance.

### SUMMARY OF THE INVENTION

An object of the present invention is to provide electronic component mounting method and apparatus which are capable of achieving higher operational speed by varying the driving amount for intermittently feeding of an electronic component according to the electronic component's type in view of the issues of the above-described prior art.

### BRIEF DESCRIPTION OF DRAWINGS

FIG. 1 is a perspective view of a general schematic of an electronic component mounting apparatus according to the present invention;

FIG. 2 is a perspective view showing in detail of a component feed unit of the electronic component mounting apparatus according to the present invention;

FIG. 3A is a sectional plan view showing a feed drive changeover unit, which is an essential part of the electronic component mounting apparatus, according to a first embodiment of the present invention;

FIG. 3B is a front view showing the fee drive changeover unit, which is an essential part of the electronic component mounting apparatus, according to the first embodiment of the present invention;

FIG. 4 is a view showing the electronic component mounting apparatus in a state of having a large intermittent feed amount according to the first embodiment of the present invention;

FIG. 5 is a view showing the electronic component mounting apparatus in a state of having a small intermittent feed amount according to the first embodiment;

FIG. 6 is a view showing a position of a pivot pin in the electronic component mounting apparatus according to the first embodiment;

FIG. 7A is a front view showing a feed drive changeover unit in a second embodiment of the present invention;

FIG. 7B is a side view showing the feed drive changeover unit in the second embodiment of the present invention;

FIG. 8A is a side view showing the feed lever driving unit in the second embodiment;

FIG. 8B is a front view showing the feed lever driving unit in the second embodiment;

FIG. 8C is a top view showing the feed lever driver driving unit in the second embodiment;

FIG. 9A is a top view showing an intermittent-feed amount changeover stopper unit in the second embodiment;

FIG. 9B is a side view showing the intermittent-feed amount changeover stopper unit in the second embodiment;

FIG. 10A is a front view of a component feed driving unit in an electronic component mounting apparatus according to the prior art; and

FIG. 10B is a side view of the component feed driving unit in the electronic component mounting apparatus according to the prior art.

### DESCRIPTION OF THE PREFERRED EMBODIMENTS

An electronic component mounting method of the present invention includes picking up (sucking) an electronic component by a pickup (suction) nozzle from a component feed unit. A component feed unit intermittently feeds taped electronic components according to a swing driving amount given to a feed lever. The picked-up electronic component is mounted onto a board. The method comprises: a first step of previously setting a relationship between types of the electronic components and intermittent component-feed amounts for the component feed unit, and recognizing a type of an electronic component prior to its take out from the component feed unit; a second step of selecting an intermittent feed amount corresponding to the type of the electronic component recognized in the first step; and a third step of adjusting the swing driving amount for the feed lever of the component feed unit according to the intermittent feed amount selected in the second step.

Preferably, a plurality of lever driving units having different swing driving amounts for the feed lever can be used, and one lever driving unit according to the intermittent feed amount can be driven.

An electronic component mounting apparatus of the present invention also, comprises: a component feed unit for accommodating electronic components therein so as to allow the electronic components to be intermittently fed; a recognition means for recognizing a type of an electronic component prior to its take out from the component feed unit; a mounting unit for picking up an electronic component from the component feed unit and mounting the electronic component to a specified position on a board; a component feed driving unit for driving the component feed unit to intermittently feed the electronic components; and a control unit for selecting an intermittent feed amount of the component feed unit according to the type of the electronic component recognized by the recognition means, and controlling the component feed driving unit to intermittently feed the electronic component by the selected specified amount.

Preferably, the component feed unit comprises a feed lever for intermittently feeding the electronic components, and the component feed driving unit comprises a lever driving unit for driving the feed lever. Also, the lever driving unit has driving-amount variable means for arbitrarily varying the swing driving amount for the feed lever. Otherwise, the electronic component mounting apparatus, preferably, further comprises a plurality of lever driving units having different swing driving amounts for the feed lever, and a selection means for selecting an arbitrary lever driving unit.

According to the electronic component mounting method and apparatus of the present invention, the relationship between the type of electronic components and the intermittent component-feed amount for the component feed unit is previously set. The driving amount for intermittently feeding the electronic components is varied according to the type of an electronic component recognized prior to its takeout from the component feed unit, so that the feed driving amount can be set to a minimal required amount. Thus, highspeed mounting can be achieved.

Also, when the apparatus comprises a component feed unit for intermittently feeding taped electronic components, the electronic component's type is recognized and a tape is driven to intermittently feed according to the intermittent feed amount which corresponds to the electronic component's type. Thus, the feed driving amount can automatically be set to a minimum required amount so that high-speed mounting can be achieved.

Furthermore, the feed lever of the component feed unit is driven to swing according to the intermittent feed amount for taped electronic components. The swing driving amount for the feed lever is changed according to the intermittent feed amount. A lever driving unit allows the swing driving amount for the feed lever to be arbitrarily changed according to the intermittent feed amount. Likewise, a plurality of lever driving units having different swing driving amounts for the feed lever can be used and changed over so that either one of them can be operated according to the intermittent feed amount. Thus, the driving amount for the feed lever can be controlled to a minimum required amount by using simple construction and control so that high-speed mounting can be realized.

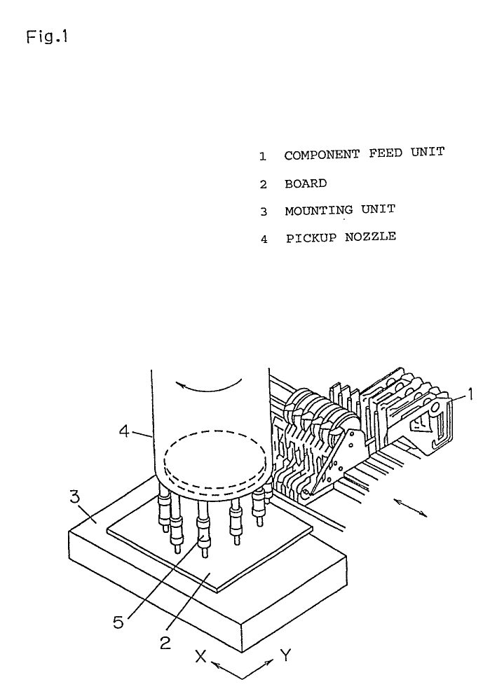

An electronic component mounting apparatus according to a first embodiment the present invention is described below with reference to the accompanying drawings. [00321 First, the electronic component mounting apparatus is described with references to FIG. 1. As shown in FIG. 1, the electronic component mounting apparatus includes a positioning table 3 for positioning a component feed unit 1 which accommodates electronic components therein and automatically feeds them. Electronic components are mounted in two directions perpendicular to each other (in X- and Y- directions in the drawing) onto board 2. The apparatus, also, includes a mounting unit 4 for picking up an electronic component automatically fed from the component feed unit 1. The electronic component which is in a component pickup position is picked up by a pickup nozzle 5 and then transferred and mounted to a specified position on the positioned board 2.

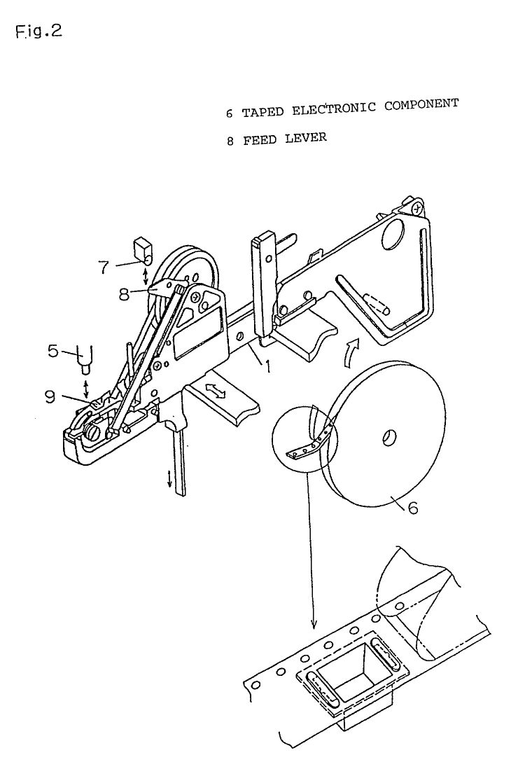

The component feed unit 1 is constructed as shown in FIG. 2. Taped electronic components 6 are fitted to the component feed unit 1. As a feed driving roller 7 moves up and down, a feed lever 8 swings up and down subordinately, so that the taped electronic components 6 are intermittently fed by a specified amount. As a result, an electronic component 6 is positioned to a specified position 9. Then, the pickup nozzle 5 moves up and down, by which the electronic component 6 is vacuum-picked up and afterwards mounted onto the board 2.

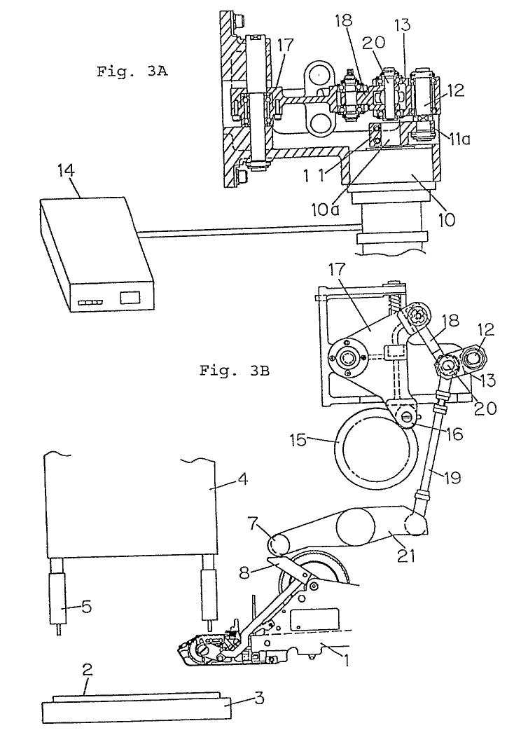

FIGS. 3A, 3B show the general construction of the electronic component mounting apparatus according to the first embodiment of the present invention. Further, FIGS. 3A, 3B show a detailed construction of the feed drive changeover unit. The feed drive changeover unit allows the up-and-down moving amount of the feed driving roller 7 to be variable in order to create an intermittent feed amount for the electronic component.

Referring to FIGS. 3A, 3B, the component feed unit 1, like the one as shown in FIG. 2, swings the feed lever 8 up and down to thereby intermittently feed the electronic component by a specified amount.

A lever block 11 is fixed to an output shaft 10a of a changeover motor 10 which arbitrarily changes over the swing driving amount for the feed lever 8. One end of a pivot pin 12 is fixed to an end portion la of the lever block 11. One end of a link block 13 is pivotally held to the other end of the pivot pin 12. A control unit 14 selects an intermittent feed amount for the tape according to the electronic component's type recognized by a recognition means. Control unit 14 controls the rotational position of the changeover motor 10 according to the recognized intermittent feed amount so that the position of the pivot pin 12 is moved via the lever block 11. For example, a person recognizes the electronic component's type and enters the type into the control unit 14. The control unit 14 stores previously entered intermittent feed amounts for corresponding types of electronic components. Then, the control unit 14 selects the intermittent feed amount corresponding to the electronic component. Control unit 14 controls the rotational position of the changeover motor 10 according to the intermittent feed amount, thereby moving the position of the pivot pin 12 via the lever block 11.

This can be automated by using a recognition means, such as a camera, that recognizes the electronic component's type instead of a person who recognizes the electronic component's type.

It is, also, possible that a person recognizes the type of an electronic component and enters an intermittent feed amount into the control unit 14.

A cam plate 15 is driven to rotate about a fixed axis, and is linked with the mounting operation. A roller 16 is rotatably fitted to one end of a tilted-L shaped driving lever 17. The driving lever 17 has its intermediate portion pivotally supported. The roller 16 is engaged with the cam plate 15. One end of a first coupling link 18 is coupled to the other end of the driving lever 17. The other end of the first coupling link 18, the other end of the link block 13, and one end of a second coupling link 19 are coupled together with a coupling pin 20. The other end of the second coupling link 19 is coupled to one end of a feed driving lever 21. The feed driving lever 21 has its intermediate portion pivotally supported. The feed driving roller 7 is fitted to the other end of the feed driving lever 21 and engaged with the feed lever 8 of the component feed unit 1.

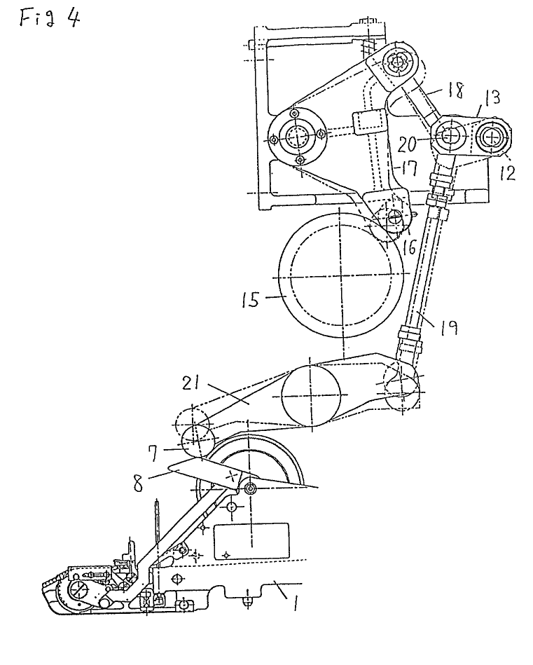

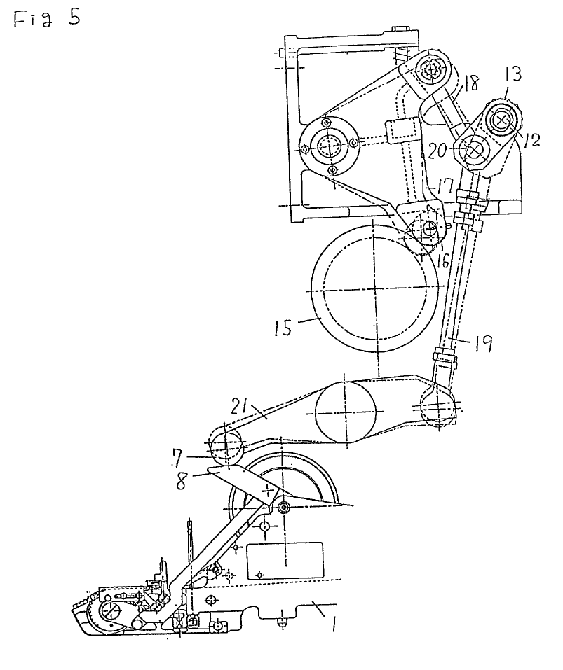

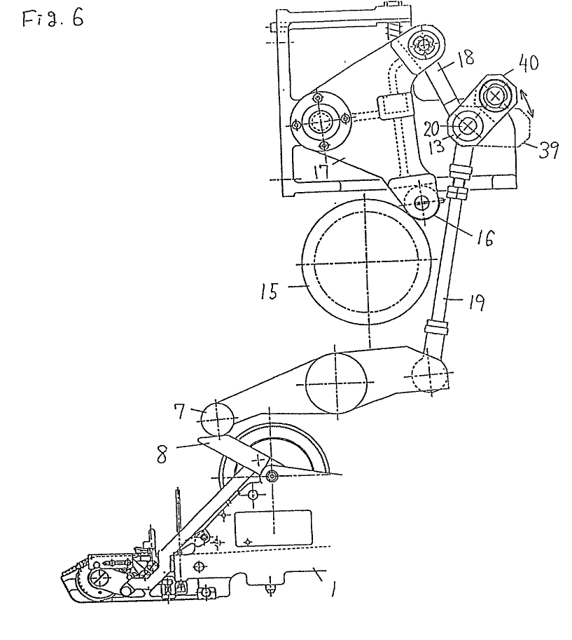

With this arrangement, the method for controlling the intermittent feed amount for an electronic component according to its type is next described. The following describes a case in which an electronic component requires a large feed amount such as ICs, and a case in which an electronic component requires a small feed amount, such as chip components. FIGS. 4 and 5, respectively, show the operation of the electronic component mounting apparatus for large and small intermittent feed amounts. The positional relation at the maximum movement in the apparatus is represented by using a solid line and a two dot chain line. FIG. 6 shows that positions of the pivot pin are changed over by the changeover motor.

The type of the electronic component is first recognized by the recognition means, and the intermittent feed amount is selected according to the recognized electronic component's type. After this, the following operation is carried out.

When an electronic component requires a large feed amount, the changeover motor 10 is rotated. The pivot pin 12 is moved to a position shown in FIG. 4 (a position indicated by 39 in FIG. 6) via the lever block 11. The swinging direction of the other end of the link block 13 becomes generally aligned with the swinging direction of the other end of the driving lever 17. As a result, the swinging amount of the other end of the driving lever 17 is transferred to one end of the feed driving lever 21 via the first and second coupling links 18, 19 without being reduced by very much.

As the driving lever 17 swings along with the rotation of the cam plate 15, the first and second coupling links 18, 19 move up and down while being regulated by the link block 13 which swings about the pivot pin 12. The feed driving lever 21 swings along with the movement of the coupling links 18, 19, causing the feed driving roller 7 to move up and down. The movement of the driving roller 7 causes the feed lever 8 to swing. As a result, the electronic components are intermittently fed by the component feed unit. In this case, because the swinging amount of the driving lever 17 is transferred to the feed driving lever 21 without being reduced by very much, the electronic components are intermittently fed in large steps.

In the case of an electronic component that requires a small feed amount, the changeover motor 10 is rotated so that the pivot pin 12 is moved to a position shown in FIG. 5 (a position indicated by 40 in FIG. 6) via the lever block 11. The swinging direction of the other end of the link block 13 is aligned with a direction that crosses the swinging direction of the other end of the driving lever 17. The swinging amount of the other end of the driving lever 17 is transferred to one end of the feed driving lever 21 while being reduced to a large extent. As a result, even if the driving lever 17 swings in a similar manner along with the rotation of the cam plate 15, the electronic components are intermittently fed at a smaller extent.

As described above, the position of the pivot pin 12 is changed by rotating the lever block 11 by means of the changeover motor 10. The vertical movement of the feed driving roller 7 is variably adjusted so that the swinging amount for the feed lever 8 of the component feed unit 1 can be changed. Thus, the intermittent feed drive can be changed while an optimum swinging amount for the feed lever 8 is selected according to the electronic component's type.

As described above in the first embodiment, by recognizing the type of an electronic component and driving the tape by an intermittent feed amount corresponding to the electronic component's type, the feed driving amount can automatically be set to a minimum required amount, so that high-speed mounting can be achieved.

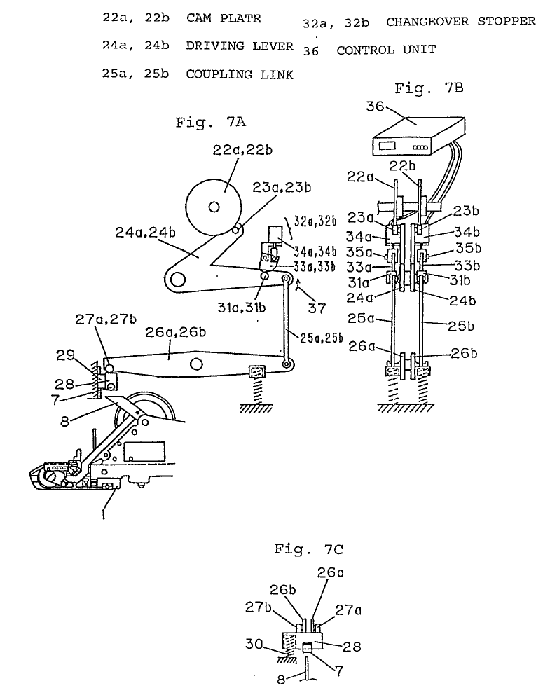

A second embodiment of the present invention is described with reference to FIGS. 7A, 7B, 7C, 8A, 8B, 8C, 9A, and 9B. The recognition means for the electronic component's type is similar to that described in the first embodiment.

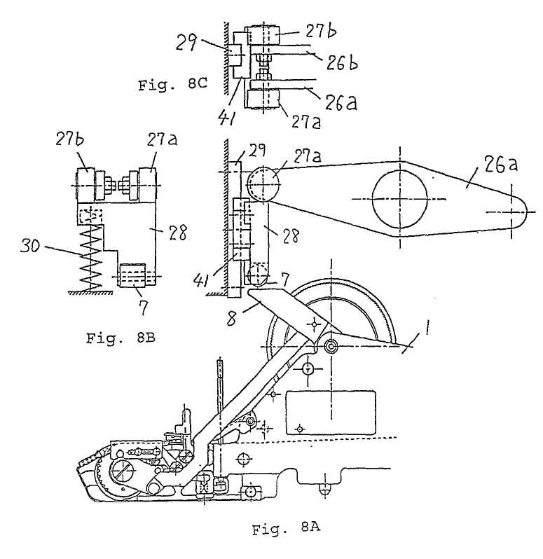

In this second embodiment, there are two juxtaposed systems for a lever driving unit comprising cam plates 22a, 22b, rollers 23a, 23b, driving levers 24a, 24b, coupling links 25a, 25b, feed driving levers 26a, 26b, and rollers 27a, 27b fitted to the other ends of the feed driving levers 26a, 26b, all of which are coupled to one another sequentially. In this case, the driving levers 24a, 24b and the feed driving levers 26a, 26b are partly pivotally supported. Then, as shown in FIGS. 8A, 8B, 8C, the rollers 27a, 27b are engaged with a block 28 having a pack 41 which is vertically movably supported by a guide 29. The block 28 is biased upward by a spring 30. The feed driving roller 7 is fitted to this block 28, and engaged with the feed lever 8 of the component feed unit 1.

Therefore, as the driving levers 24a, 24b swing along with the rotation of the cam plates 22a, 22b, the feed driving levers 26a, 26b swing via the coupling links 25a, 25b. The feed lever 8 of the component feed unit 1 is driven to swing by the feed driving roller 7 via the rollers 27a, 27b and the block 28. In this case, the component feed unit 1 is the same as that described in the first embodiment.

One cam plate 22a is formed into such a shape so as to swing the feed lever 8 by a large amount, while the cam plate 22b is formed into such a shape so as to swing the feed lever 8 by a small amount.

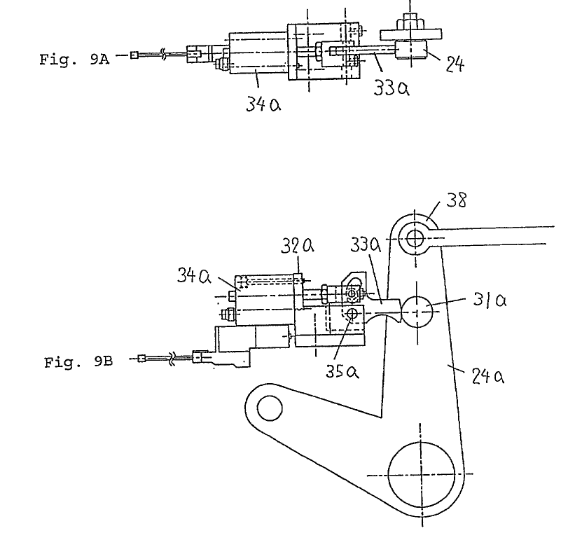

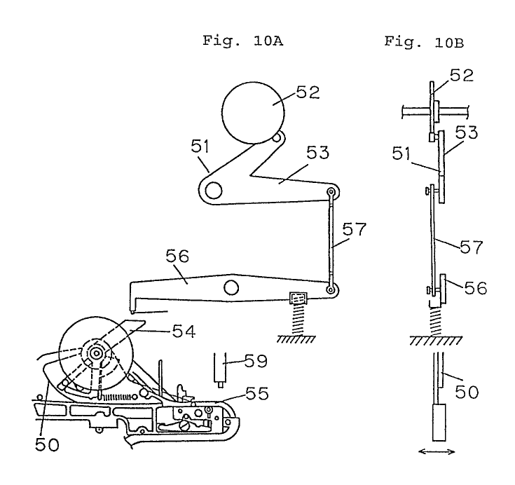

As shown in FIGS. 9A, 9B, cam followers 31a, 31b are fitted to side faces of the driving levers 24a, 24b in proximity to the other ends thereof. Cam followers 31a, 31b are arranged so as to be able to engage with stopper levers 33a, 33b of changeover stoppers 32a, 32b, respectively. The stopper levers 33a, 33bare driven by cylinders 34a, 34b in order to rotate about pins 35a, 35b. The stopper levers 33a, 33bare arranged so as to be switchable between positions where they engage the cam followers 31a, 31b so as to block the other end portion 38 of the driving lever 24a, 24b from moving upwards. At the positions where stopper levers 33a, 33bdo not engage the cam followers 31a,31b, the other end portion 38 of the driving lever 24a can move upward. The cylinders 34a, 34b are selectively operable by a control unit 36. The control unit 36 recognizes the intermittent feed amount for the tape according to the electronic component's type and actuates either one of the cylinders 34a, 34b according to the recognized intermittent feed amount. The actuated stopper lever 33aor 33bengages with the cam follower 3 la or 3 lb. so that even if the cam plate 22a or 22b comes to a root (bottom) position (a position where the roller subordinates closest to the rotational center of the cam plate), the driving lever 24a or 24b will not swing in the direction shown by arrow 37.

With the above arrangement, by actuating the changeover stopper 32a or 32b according to the electronic component's type with the control unit 36, the feed lever 8 of the component feed unit 1 is driven to swing by a swinging amount corresponding to the shape of either cam plate 22a or 22b . The intermittent feed can be driven while an optimum swinging amount for the feed lever 8 is selected according to the electronic component's type.

In this way, by driving the taping into intermittent feed according to an intermittent feed amount corresponding to the electronic component's type, the feed driving amount can automatically be set to a minimum required amount, so that high-speed mounting can be achieved.

As apparent from the above description and according to the electronic component mounting method of the present invention, the feed driving amount for intermittently feeding an electronic component is made variable according to the electronic components type so that the feed driving amount can be set to a minimum required amount. The electronic components can be intermittently fed in a shorter amount of time. Thus, highspeed mounting can be achieved.

Also, according to the electronic component mounting method and apparatus of the present invention, the apparatus includes a component feed unit for intermittently feeding taped electronic components. The electronic component's type is recognized and the tape is intermittently fed according to the intermittent feed amount corresponding to the electronic component's type. Thus, the feed driving amount can automatically be set to a minimum required amount so that high-speed mounting can be achieved.

Furthermore, the feed lever of the component feed unit is driven to swing according to the intermittent feed amount for the taped electronic components. The swing driving amount for the feed lever can be changed over according to the intermittent feed amount by using a lever driving unit that allows the swing driving amount for the feed lever to be arbitrarily changed over by using a plurality of lever driving units having different swing driving amounts for changing over to either one of them. Thus, the driving amount for the feed lever can be controlled to a minimum required amount with simple construction and control, by which high-speed mounting can be realized.

Although the present invention has been fully described in conjunction with preferred embodiments thereof with reference to the accompanying drawings, various changes and modifications will be apparent to those skilled in the art. Therefore, unless otherwise such changes and modifications depart from the scope of the present invention as defined by the appended claims, they should be construed as included therein.

We claim:

1. An electronic component feeding method for feeding electronic components of different types to be removed from a component feed unit that has a feed lever, the method comprising:
setting a relationship between electronic component types in the component feed unit and intermittent component-feed amounts for the component feed unit;
determining the types of electronic components to be removed from the component feed unit;
selecting intermittent component-feed amounts corresponding to the types of electronic components determined during said determining; and
varying swing driving amounts of the feed lever of the component feed unit according to said selected intermittent component-feed amounts by applying a changeable external force to the feed lever by changing an amount of movement of a feed driving lever contacting the feed lever.

2. The method according to claim 1, wherein a plurality of lever driving units having different swing driving amounts for the feed lever are used, and wherein said varying of the swing driving amounts further comprises changing over to one of said plurality of lever driving units according to said selected intermittent component-feed amounts.

3. The method according to claim 1, wherein said varying of the swing driving amounts further comprises changing an amount of vertical movement of the feed driving lever contacting the feed lever.

4. The method according to claim 1, wherein said varying of the swing driving amounts further comprises applying the external force to the feed lever so as to move the feed lever.

5. The method according to claim 1, further comprising moving a tape having electronic components mounted thereon based on the swing driving amounts of the feed lever, wherein said varying of the swing driving amounts comprises varying the swing driving amounts during said moving of the tape.

6. The method according to claim 1, wherein said varying of the swing driving amounts further comprises causing the feed lever to pivot about a pivot point an amount corresponding to the intermittent component-feed amounts.

7. The method according to claim 6, further comprising advancing a tape having the electronic components mounted thereon by linking the feed lever to the tape such that when the feed lever is pivoted about the pivot point, the feed lever pushes the tape forward a distance equal to one of the intermittent component-feed amounts.

8. An electronic component feeding method for feeding electronic components of different types to be removed from a component feed unit that has a feed lever, the method comprising:
setting a relationship between electronic component types in the component feed unit and intermittent component-feed amounts for the component feed unit;
determining the types of electronic components to be removed from the component feed unit;
selecting intermittent component-feed amounts corresponding to the types of electronic components determined in said determining; and
varying swing driving amounts of the feed lever of the component feed unit according to said selected intermittent component-feed amounts by applying a changeable external force to the feed lever so as to cause the feed lever to pivot about a pivot point an amount corresponding to the intermittent component-feed amounts.

9. The method according to claim 8, wherein a plurality of lever driving units having different swing driving amounts for the feed lever are used, and wherein said varying of the swing driving amounts further comprises changing over to one of said plurality of lever driving units according to said selected intermittent component-feed amounts.

10. The method according to claim 8, wherein said varying of the swing driving amounts further comprises changing an amount of vertical movement of a feed driving lever contacting the feed lever.

11. The method according to claim 8, wherein said varying of the swing driving amounts further comprises applying the external force to the feed lever so as to move the feed lever.

12. The method according to claim 8, further comprising moving a tape having electronic components mounted thereon based on the swing driving amounts of the feed lever, wherein said varying of the swing driving amounts further comprises varying the swing driving amounts during said moving of the tape.

13. The method according to claim 8, further comprising advancing a tape having the electronic components mounted thereon by linking the feed lever to the tape such that when the feed lever is pivoted about the pivot point, the feed lever pushes the tape forward a distance equal to one of the intermittent component-feed amounts.

14. The method according to claim 8, wherein said varying of the swing driving amounts further comprises pivoting a feed driving lever about a fulcrum such that an end of the feed driving lever is moved so as to apply the external force to the feed lever.

15. The method according to claim 14, wherein said varying of the swing driving amounts further comprises operating a changeover motor to change a distance through which the feed driving lever is pivoted so as to change the external force applied by the feed driving lever to the feed lever.

16. An electronic component feeding method for feeding electronic components of different types to be removed from a component feed unit that has a feed lever, the method comprising:
setting a relationship between electronic component types in the component feed unit and intermittent component-feed amounts for the component feed unit;
determining the types of electronic components to be removed from the component feed unit;
selecting intermittent component-feed amounts corresponding to the types of electronic components determined during said determining; and
varying swing driving amounts of the feed lever of the component feed unit according to said selected intermittent component-feed amounts, said varying of the swing driving amounts comprising:
pivoting a feed driving lever about a fulcrum such that an end of the feed driving lever is moved;
operating a changeover motor to change a distance through which the feed driving lever is pivoted so as to change an amount of movement of the end of the feed driving lever;
contacting the feed lever with the end of the feed driving lever so as to apply external force to the feed lever to generate a swing driving amount of the feed lever; and
changing the external force applied by the feed driving lever to the feed lever by changing the distance through which the feed driving lever is pivoted so as to vary the swing driving amount of the feed lever.

17. The method according to claim 16, wherein a plurality of lever driving units having different swing driving amounts for the feed lever are used, and wherein said varying of the swing driving amounts further comprises changing over to one of said plurality of lever driving units according to said selected intermittent component-feed amounts.

18. The method according to claim 16, wherein said operating of the changeover motor to change the distance through which the feed driving lever is pivoted comprises changing an amount of vertical movement of the end of the feed driving lever contacting the feed lever.

19. The method according to claim 16, further comprising moving a tape having electronic components mounted thereon based on the swing driving amounts of the feed lever, wherein said varying of the swing driving amounts comprises varying the swing driving amounts during said moving of the tape.

20. The method according to claim 16, wherein said contacting of the feed lever with the end of the feed driving lever comprises pivoting the feed lever about a pivot point a distance corresponding to the swing driving amount;
the method further comprising advancing a tape having the electronic components mounted thereon by linking the feed lever to the tape such that when the feed lever is pivoted about the pivot point, the feed lever pushes the tape forward a distance equal to one of the intermittent component-feed amounts.
